(19) United States
(12) Patent Application Publication
(10) Pub. No.: US 2018/0315919 A1
(43) Pub. Date: Nov. 1, 2018

(54) SEMICONDUCTOR DEVICE

(71) Applicant: ABLIC Inc., Chiba-shi (JP)

(72) Inventors: Yohei OGAWA, Chiba-shi (JP); Takaaki HIOKA, Chiba-shi (JP)

(21) Appl. No.: 15/964,923

(22) Filed: Apr. 27, 2018

(30) Foreign Application Priority Data
Apr. 28, 2017 (JP) 2017-090394

(51) Int. Cl. H01L 43/06; H01L 43/04

(52) U.S. Cl. CPC H01L 43/065; H01L 43/04

(57) ABSTRACT

Provided is a semiconductor device including a Hall element, in which a depletion layer is prevented from spreading to a magnetism sensing portion more reliably, and thus variations in characteristic are reduced. The semiconductor device, including: a semiconductor substrate of a first conductivity type; and a Hall element formed on the semiconductor substrate, the Hall element having: a magnetism sensing portion of a second conductivity type formed on the semiconductor substrate so as to be separated from the semiconductor substrate; and a semiconductor layer of the second conductivity type formed so as to surround side surfaces and a bottom surface of the magnetism sensing portion on the semiconductor substrate and has a lower concentration than a concentration of the magnetism sensing portion and a uniform concentration distribution.

### RELATED APPLICATIONS

This application claims priority under 35 U.S.C. § 119 to Japanese Patent Application No. 2017-090394 filed on Apr. 28, 2017, the entire content of which is hereby incorporated by reference.

### BACKGROUND OF THE INVENTION

### 1. Field of the Invention

The present invention relates to a semiconductor device, and more particularly, to a semiconductor device including a Hall element configured to detect a magnetic field in a direction perpendicular to a main surface of a semiconductor substrate.

### 2. Description of the Related Art

A Hall element is capable of detecting a magnetic field by a Hall effect, and is used for various purposes because it is possible to detect a position or an angle in a non-contact manner when the Hall element is used as a magnetic sensor. In general, there is widely known a horizontal Hall element capable of detecting a magnetic field in a perpendicular direction.

The horizontal Hall element includes, for example, a magnetism sensing portion formed on a semiconductor substrate, and a pair of input electrodes and a pair of output electrodes formed in a surface of the magnetism sensing portion.

When a magnetic field is applied in a direction perpendicular to a main surface of the semiconductor substrate, and a current flows between the pair of input electrodes, a Lorentz force is generated in a direction perpendicular to both of the current and the magnetic field by the action of the magnetic field. This generates an electromotive force between the pair of output electrodes, and the magnetic field can be detected by obtaining the electromotive force as an output voltage.

In such a horizontal Hall element, for example, there is a problem in that a width of a depletion layer spread in the magnetism sensing portion varies depending on a voltage applied to the input electrodes, and thus a resistance value of the magnetism sensing portion serving as a current path varies, with the result that variations in characteristic of the Hall element occur.

To address this problem, in a Hall element described in Japanese Patent Application Laid-open No. 2013-149838, an N-type first well layer serving as a magnetism sensing portion and an N-type second well layer that surrounds the outer side of the first well layer and has a lower concentration than that of the first well layer are formed in a P-type semiconductor substrate. With this structure, it is prevented that a depletion layer formed between the semiconductor substrate and the second well layer spreads to reach the first well layer. As a result, the magnetism sensing portion (first well layer) is not affected by the depletion layer, and hence its resistance value is prevented from varying. Consequently, it is possible to reduce variations in characteristic.

However, in the structure of Japanese Patent Application Laid-open No. 2013-149838, the following problem arises.

Specifically, the second well layer formed outside of the first well layer and has a lower concentration than that of the first well layer, is formed by introducing N-type impurities into the semiconductor substrate by, for example, ion implantation, and hence a concentration distribution of the impurities is generated in the second well layer. When the second well layer has a concentration distribution as described above, the depletion layer formed in a PN junction portion between the second well layer and the semiconductor substrate can hardly have a uniform thickness by being affected by the concentration distribution of the second well layer. For that reason, the depletion layer may extend into the first well layer in some places. Consequently, the first well layer serving as the magnetism sensing portion is affected by the depletion layer in some places, and thus its resistance value varies, with the result that variations in characteristic occur.

Meanwhile, the so-called offset voltage, which is output when no magnetic field is applied, is generally removed (offset cancellation is performed) by spinning current method (see, for example, Japanese Patent Application Laid-open No. H06-186103). However, in the Hall element described in Japanese Patent Application Laid-open No. 2013-149838, as described above, it is difficult for the depletion layer to spread uniformly. For that reason, the offset voltage cannot be completely removed and disadvantageously remains in offset cancellation performed by switching the current flowing directions (the current application directions) using spinning current method for the Hall element described in Japanese Patent Application Laid-open No. 2013-149838 since the spreading of the generated depletion layer is different depending on each current application direction.

### SUMMARY OF THE INVENTION

In view of the above, the present invention has an object to provide a semiconductor device including a Hall element, in which spreading of a depletion layer to a magnetism sensing portion is prevented more reliably, and thus variations in characteristic are reduced.

In one embodiment of the present invention, there is provided a semiconductor device including: a semiconductor substrate of a first conductivity type; and a Hall element formed on the semiconductor substrate, the Hall element having: a magnetism sensing portion of a second conductivity type formed on the semiconductor substrate so as to be separated from the semiconductor substrate; and a semiconductor layer of the second conductivity type formed so as to surround side surfaces and a bottom surface of the magnetism sensing portion on the semiconductor substrate and having a lower concentration than a concentration of the magnetism sensing portion and a uniform concentration distribution.

According to the present invention, a depletion layer is generated in a PN junction portion between the semiconductor substrate of the first conductivity type and the semiconductor layer of the second conductivity type. This depletion layer spreads toward the semiconductor substrate side and the semiconductor layer side both, and of the depletion layer, a portion that spreads toward the semiconductor layer side spreads toward the magnetism sensing portion. However, the semiconductor substrate and the magnetism sensing portion are not in direct contact with each other because the semiconductor layer is interposed between the semiconductor substrate and the magnetism sensing portion, and the concentration of the magnetism sensing portion is higher than the concentration of the semiconductor layer, and hence it is possible to prevent the depletion layer from reaching the magnetism sensing portion. Further, the semiconductor layer has a uniform concentration distribution, and hence the formed depletion layer uniformly spreads at any part of the junction portion with the semiconductor substrate. As a result, the depletion layer can be reliably prevented from spreading to the magnetism sensing portion, and thus variations in characteristic of the Hall element can be reduced.

Consequently, the offset voltage can be sufficiently removed in the offset cancellation using spinning current method since the spreading of the generated depletion layer becomes almost even on each current application in spite of switching the current application directions.

### BRIEF DESCRIPTION OF THE DRAWINGS

Embodiments of the invention will now be described, by way of example, with reference to the accompanying drawings, in which:

FIG. 1A is a plan view of a semiconductor device according to a first embodiment of the present invention, and FIG. 1B is a cross-sectional view taken along the line A-A of FIG. 1A;

FIG. 2 is a cross-sectional view of a semiconductor device according to a second embodiment of the present invention;

FIG. 3 is a cross-sectional view of a semiconductor device according to a third embodiment of the present invention; and

FIG. 4 is a cross-sectional view of a semiconductor device according to a fourth embodiment of the present invention.

### DETAILED DESCRIPTION OF THE EMBODIMENTS

Embodiments of the present invention will now be described herein with reference to accompanying drawings.

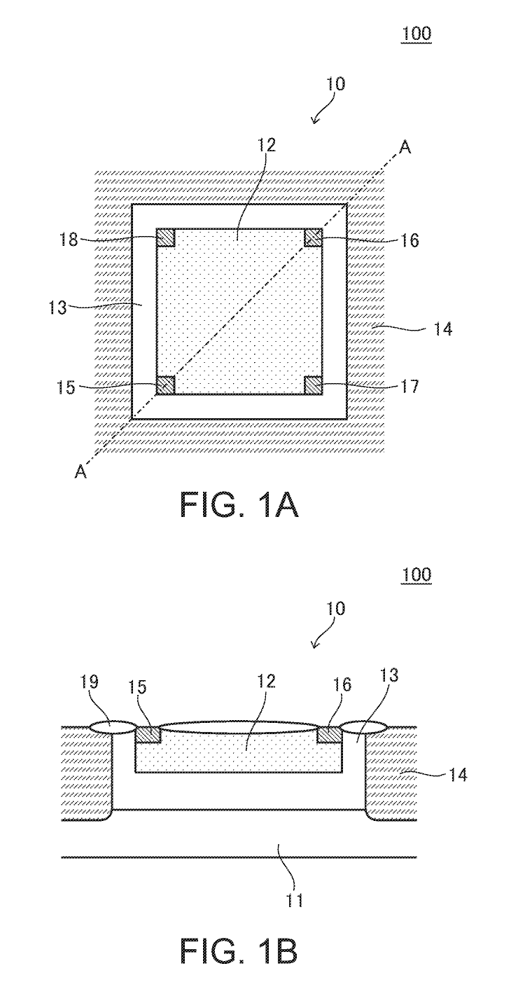

FIGS. 1A and 1B are views for illustrating a semiconductor device 100 according to a first embodiment of the present invention, in which FIG. 1A is a plan view, and FIG. 1B is a sectional view taken along the line A-A of FIG. 1A.

As illustrated in FIGS. 1A and 1B, the semiconductor device 100 according to the first embodiment includes a P-type (first conductivity-type) semiconductor substrate 11, a Hall element 10, which is formed on the semiconductor substrate 11, and a P-type element isolation diffusion layer 14 which is formed so as to surround the periphery of the Hall element 10.

The Hall element 10 includes an N-type (second conductivity-type) magnetism sensing portion 12 formed on the semiconductor substrate 11 so as to be separated from the semiconductor substrate 11, an N-type semiconductor layer 13 formed so as to surround side surfaces and a bottom surface of the magnetism sensing portion 12 on the semiconductor substrate 11 and having a lower concentration than that of the magnetism sensing portion 12 and a uniform concentration distribution, and electrodes 15 to 18 formed in a surface of the magnetism sensing portion 12 and formed of N-type impurity layers having a higher concentration than that of the magnetism sensing portion 12.

Further, an insulating film (for example, silicon oxide film) 19 is formed so as to cover surfaces of the magnetism sensing portion 12 and the semiconductor layer 13 in a region other than regions in which the electrodes 15 to 18 and the element isolation diffusion layer 14 are formed. Thus, current flowing in parallel to a main surface of the semiconductor substrate 11 can be reduced in the surface of the magnetism sensing portion 12.

With this structure, a depletion layer generated in a PN junction portion between the semiconductor substrate 11 and the semiconductor layer 13 spreads toward the semiconductor substrate 11 side and the semiconductor layer 13 side both, and the depletion layer spreading toward the semiconductor layer 13 side spreads toward the magnetism sensing portion 12. However, the semiconductor substrate 11 and the magnetism sensing portion 12 are not in direct contact with each other because the semiconductor layer 13 is interposed between the semiconductor substrate 11 and the magnetism sensing portion 12, and the magnetism sensing portion 12 has a higher concentration than that of the semiconductor layer 13. Thus, it is possible to prevent the depletion layer from reaching the magnetism sensing portion 12.

Further, the semiconductor layer 13 has a uniform concentration distribution, and hence the formed depletion layer uniformly spreads at any part of the junction portion with the semiconductor substrate 11. As a result, the depletion layer can be reliably prevented from spreading to the magnetism sensing portion 12, and variations in characteristic of the Hall element can be reduced.

Consequently, spreading of the depletion layer formed on respective current application can be made almost equal even when the current application directions are switched in the offset cancellation for the Hall element 10 of the first embodiment by the spinning current method. Thus, the offset voltage can be sufficiently reduced.

The semiconductor layer 13 which has a uniform concentration distribution of N-type impurities is formed by, for example, epitaxial growth on the semiconductor substrate 11. Further, the magnetism sensing portion 12 is formed by, for example, introducing N-type impurities into the semiconductor layer 13 formed by epitaxial growth.

An impurity concentration of the semiconductor layer 13 formed by epitaxial growth is preferred to be, for example, from about 1×10¹⁵ atoms/cm³ to about 1×10¹⁶ atoms/cm³. It is generally known that the magnetic sensitivity of the Hall element increases in proportion to mobility thereof, and hence a lower impurity concentration of the magnetism sensing portion 12 is more preferred. However, an impurity concentration of the magnetism sensing portion 12 is required to be set higher than that of an impurity concentration of the semiconductor layer 13 so that it is reliably prevented that the depletion layer formed in the PN junction portion between the semiconductor substrate 11 and the semiconductor layer 13 reaches the magnetism sensing portion 12. For that reason, the impurity concentration of the magnetism sensing portion 12 is preferred to be, for example, from about 1×10¹⁶ atoms/cm³ to about 1×10¹⁸ atoms/cm³.

Further, with regard to a depth (thickness) direction, depths (thicknesses) of the magnetism sensing portion 12 and the semiconductor layer 13 are required to be appropriately set so that the depletion layer formed in the PN junction portion between the semiconductor substrate 11 and the semiconductor layer 13 does not reach the magnetism sensing portion 12. For example, when the depth (thickness) of the magnetism sensing portion 12 is set to from about 3 μm to about 5 μm, the depth (thickness) of the semiconductor layer 13 is preferred to be set to from about 6 μm to about 9 μm.

The element isolation diffusion layer 14 is formed so as to be deeper than the bottom of the semiconductor layer 13 and to reach the semiconductor substrate 11. With this structure, the Hall element 10 is electrically separated from an element, for example, a MOS transistor which is included in, for example, a circuit configured to process signals from the Hall element 10 and is formed in other regions (not shown) on the semiconductor substrate 11. When a MOS transistor or the like is arranged as described above in a region that is not shown, a well in which the MOS transistor is formed and the magnetism sensing portion 12 included in the Hall element 10 can be formed in the same step. As a result, the number of manufacturing steps can be prevented from increasing.

In the semiconductor device 100 according to the first embodiment, the P-type semiconductor substrate 11 and the N-type semiconductor layer 13 which form the PN junction both have a low concentration, and hence a junction leakage current is liable to occur at high temperature. The occurrence of the junction leakage current means that current flows to portions other than the magnetism sensing portion 12 to which current originally flows. As a result, sensitivity of the magnetism sensing portion 12 decreases, and when the offset cancellation is performed by spinning current method, the leakage currents at the time of switching the current application directions vary among the current application directions. Consequently, there arises a case in which the offset voltage cannot be completely removed.

In view of the above, description is given below of configurations, as a second to fourth embodiments of the present invention, in which the junction leakage current at high temperature is also reduced while the above-mentioned effects obtained in the semiconductor device 100 according to the first embodiment are maintained.

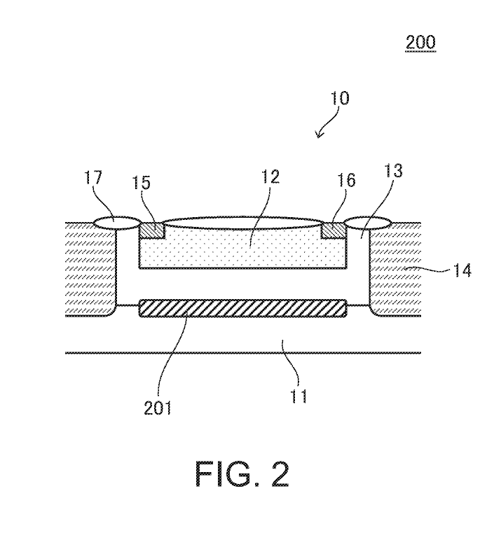

FIGS. 2, 3 and 4 are cross-sectional views for illustrating semiconductor devices 200, 300 and 400 according to the second, third and fourth embodiments of the present invention, respectively. Each of plan views thereof corresponds to the plan view of FIG. 1A, and hence illustration thereof is omitted.

The same components as those of the semiconductor device 100 illustrated in FIG. 1A and FIG. 1B are denoted by the same reference numerals, and redundant description is omitted as appropriate.

As illustrated in FIG. 2, the semiconductor device 200 according to the second embodiment further includes, in addition to the structure of the semiconductor device 100 according to the first embodiment, a P-type buried layer 201 in a lower portion of the Hall element 10 and between the P-type semiconductor substrate 11 and the N-type semiconductor layer 13.

A concentration of the P-type buried layer 201 is higher than that of the P-type semiconductor substrate 11.

In this manner, by arranging the P-type buried layer 201 having a higher concentration than that of the semiconductor substrate 11, the PN junction formed in the lower portion of the Hall element 10 is formed not between the semiconductor substrate 11 and the semiconductor layer 13 but between the P-type buried layer 201 and the N-type semiconductor layer 13.

The leakage current in the PN junction can be reduced by setting at least one of a P-type semiconductor and an n-type semiconductor forming the PN junction to have a high concentration. In the above-mentioned structure, the buried layer 201, which is one of the buried layer 201 and the semiconductor layer 13, which form the PN junction, has a high concentration. Accordingly, the junction leakage current can be reduced as compared to the semiconductor device 100 according to the first embodiment. Thus, the offset voltage can be sufficiently reduced when the offset cancellation is performed by spinning current method.

However, the semiconductor layer 13 is joined not to the semiconductor substrate 11 but to the buried layer 201 having a high concentration, and hence the depletion layer greatly spreads toward the semiconductor layer 13 side as compared to the depletion layer in the semiconductor device 100 according to the first embodiment. For that reason, in the second embodiment, the depth (thickness) and the concentration of the semiconductor layer 13 and the thickness and the concentration of the buried layer 201 should be adjusted and optimized as appropriate so that the depletion layer does not reach the magnetism sensing portion 12.

The buried layer 201 is formed by, for example, introducing P-type impurities from a surface of the semiconductor substrate 11, and then forming the semiconductor layer 13 by epitaxial growth.

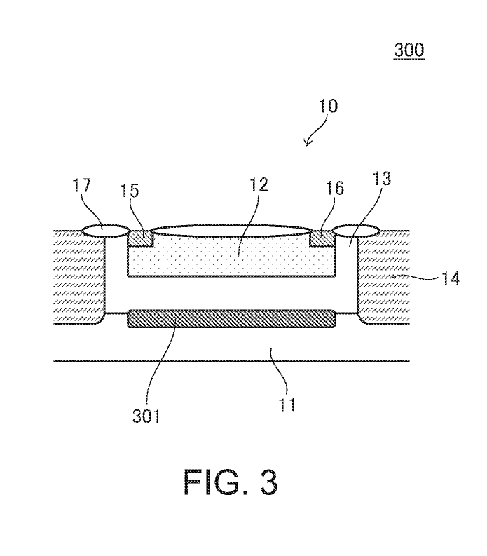

Next, as illustrated in FIG. 3, the semiconductor device 300 according to the third embodiment further includes, in addition to the structure of the semiconductor device 100 according to the first embodiment, an N-type buried layer 301 in the lower portion of the Hall element 10 and between the P-type semiconductor substrate 11 and the N-type semiconductor layer 13.

A concentration of the N-type buried layer 301 is higher than that of the N-type semiconductor layer 13.

In this manner, by arranging the N-type buried layer 301 having a higher concentration than that of the semiconductor layer 13, the PN junction formed in the lower portion of the Hall element 10 is formed not between the semiconductor substrate 11 and the semiconductor layer 13 but between the P-type semiconductor substrate 11 and the N-type buried layer 301.

With the above-mentioned structure, the buried layer 301, which is one of the semiconductor substrate 11 and the buried layer 301, which form the PN junction, has a high concentration. Accordingly, similarly to the semiconductor device 200 according to the second embodiment, the junction leakage current can be reduced as compared to the semiconductor device 100 according to the first embodiment.

Further, according to the third embodiment, with regard to the depletion layer formed in the PN junction portion between the semiconductor substrate 11 and the buried layer 301, the N-type buried layer 301 has a high concentration, and hence the depletion layer spreading toward the semiconductor layer 13 side falls within the buried layer 301, or overlaps with the semiconductor layer 13 only to a small extent even when the depletion layer spreads to exceed the buried layer 301. Accordingly, even when the thickness of the semiconductor layer 13 is reduced, the depletion layer can be prevented from reaching the magnetism sensing portion 12. Thus, when the semiconductor layer 13 is formed by epitaxial growth, its thickness can be reduced, with the result that the manufacturing cost of the semiconductor device can also be reduced.

However, when the concentration of the N-type buried layer 301 is set to be excessively high, a current that originally flows between the electrodes 15 and 16 in the magnetism sensing portion 12 is liable to flow to the buried layer 301 having low resistance. To address this, the depth (thickness) and the concentration of the semiconductor layer 13 and the thickness and the concentration of the buried layer 301 should be adjusted and optimized as appropriate.

The buried layer 301 is formed by, for example, introducing N-type impurities from the surface of the semiconductor substrate 11, and then forming the semiconductor layer 13 by epitaxial growth.

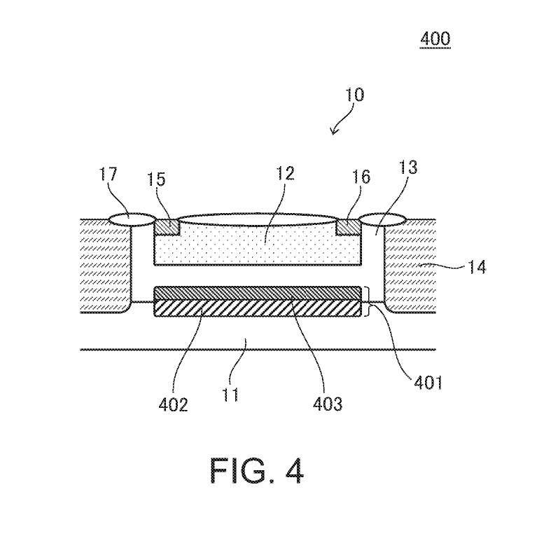

Next, as illustrated in FIG. 4, the semiconductor device 400 according to the fourth embodiment further includes, in addition to the structure of the semiconductor device 100 according to the first embodiment, a buried layer 401 in the lower portion of the Hall element 10 and between the P-type semiconductor substrate 11 and the N-type semiconductor layer 13.

The buried layer 401 includes a P-type buried layer 402 formed on the semiconductor substrate 11 side and an N-type buried layer 403 formed on the semiconductor layer 13 side so as to be in contact with an upper surface of the buried layer 402.

The P-type buried layer 402 has a higher concentration than that of the P-type semiconductor substrate 11, and the N-type buried layer 403 has a higher concentration than that of the N-type semiconductor layer 13.

In this manner, in the fourth embodiment, the PN junction formed in the lower portion of the Hall element 10 is formed not between the semiconductor substrate 11 and the semiconductor layer 13 but between the P-type buried layer 402 and the N-type buried layer 403.

With the above-mentioned structure, both the P-type buried layer 402 and the N-type buried layer 403 which form the PN junction have a high concentration. Accordingly, the junction leakage current can further be reduced as compared to the semiconductor devices 200 and 300 according to the second and third embodiments.

Further, according to the fourth embodiment, with regard to the depletion layer formed in the PN junction portion between the P-type buried layer 402 and the N-type buried layer 403, the buried layer 402 and the buried layer 403 both have a high concentration, and hence the depletion layer spreading toward the semiconductor substrate 11 side and the depletion layer spreading toward the semiconductor layer 13 side both become narrow. Thus, similarly to the semiconductor device 300 according to the third embodiment, the depletion layer spreading toward the semiconductor layer 13 side falls within the buried layer 403, or overlaps with the semiconductor layer 13 only to a small extent even when the depletion layer spreads to exceed the buried layer 403. Accordingly, even when the thickness of the semiconductor layer 13 is reduced, the depletion layer can be prevented from reaching the magnetism sensing portion 12. Thus, when the semiconductor layer 13 is formed by epitaxial growth, its thickness can be reduced, with the result that the manufacturing cost of the semiconductor device can also be reduced also in the fourth embodiment.

However, similarly to the semiconductor device 300 according to the third embodiment, when the concentration of the N-type buried layer 403 is set to be excessively high, a current that originally flows between the electrodes 15 and 16 in the magnetism sensing portion 12 is liable to flow to the buried layer 403 having low resistance. To address this, the depth (thickness) and the concentration of the semiconductor layer 13 and the thickness and the concentration of the buried layer 403 should be adjusted and optimized as appropriate.

The buried layer 401 is formed by, for example, introducing the P-type impurities slightly deeper from the surface of the semiconductor substrate 11, introducing the N-type impurities slightly shallower than the P-type impurities, and then forming the semiconductor layer 13 by epitaxial growth.

With regard to the buried layer 401, it is desired that the P-type buried layer 402 is formed on the semiconductor substrate 11 side and the N-type buried layer 403 be formed on the semiconductor layer 13 side, that is, the buried layer of the same conductivity type as that of the semiconductor substrate 11 is formed on the semiconductor substrate 11 side and the buried layer of the same conductivity type as that of the semiconductor layer 13 be formed on the semiconductor layer 13 side. An arrangement of the N-type buried layer 403 on the P-type semiconductor substrate 11 side and the P-type buried layer 402 on the N-type semiconductor layer 13 side leads to reduction of the junction leakage current as well. However, with this arrangement, depletion layers are formed in each of a PN junction portion between the buried layer 403 and the semiconductor substrate 11 and a PN junction portion between the buried layer 402 and the semiconductor layer 13. In particular, the depletion layer formed between the P-type buried layer 402 and the N-type semiconductor layer 13 greatly spreads toward the semiconductor layer 13 side of a low concentration, and thus is liable to affect the magnetism sensing portion 12.

It is apparent that the present invention is not limited to the above embodiments, but may be modified and changed without departing from the scope and spirit of the invention.

For example, the first conductivity type as the P type and the second conductivity type as the N type in the embodiments described above may be switched to set the first conductivity as the N type and the second conductivity as the P type.

What is claimed is:

1. A semiconductor device, comprising:
a semiconductor substrate of a first conductivity type; and
a Hall element formed on the semiconductor substrate,
the Hall element comprising:
a magnetism sensing portion of a second conductivity type formed on the semiconductor substrate so as to be separated from the semiconductor substrate; and
a semiconductor layer of the second conductivity type formed so as to surround side surfaces and a bottom surface of the magnetism sensing portion on the semiconductor substrate, the semiconductor layer having a lower concentration than a concentration of the magnetism sensing portion and a uniform concentration distribution.

2. The semiconductor device according to claim 1, further comprising a buried layer of the first conductivity type formed below the magnetism sensing portion and between the semiconductor substrate and the semiconductor layer, and having a higher concentration than a concentration of the semiconductor substrate.

3. The semiconductor device according to claim 1, further comprising a buried layer of the second conductivity type formed below the magnetism sensing portion and between the semiconductor layer and the semiconductor layer, and having a higher concentration than a concentration of the semiconductor layer.

4. The semiconductor device according to claim 1, further comprising a buried layer formed below the magnetism sensing portion and between the semiconductor substrate and the semiconductor layer,
the buried layer comprising:
a first buried layer of the first conductivity type formed on the semiconductor substrate side, and having a higher concentration than a concentration of the semiconductor substrate; and
a second buried layer of the second conductivity type formed on the semiconductor layer side so as to be in contact with an upper surface of the first buried layer, and having a higher concentration than a concentration of the semiconductor layer.

5. The semiconductor device according to claim 1, wherein the semiconductor layer comprises an epitaxial layer.

6. The semiconductor device according to claim 2, wherein the semiconductor layer comprises an epitaxial layer.

7. The semiconductor device according to claim 3, wherein the semiconductor layer comprises an epitaxial layer.

8. The semiconductor device according to claim 4, wherein the semiconductor layer comprises an epitaxial layer.
